(19) United States
(12) Patent Application Publication
(10) Pub. No.: US 2017/0214413 A1
(43) Pub. Date: Jul. 27, 2017

(54) JOINT SOURCE-CHANNEL CODING WITH DYNAMIC DICTIONARY FOR OBJECT-BASED STORAGE

(71) Applicant: HGST NETHERLANDS B.V., Amsterdam (NL)

(72) Inventors: Ying WANG, Bryan, TX (US); Minghai QIN, San Jose, CA (US); Zvonimir BANDIC, San Jose, CA (US)

(21) Appl. No.: 15/003,502

(22) Filed: Jan. 21, 2016

(51) Int. Cl. H03M 13/09; H03M 13/23; G06F 11/10; H04L 1/00

(52) U.S. Cl. CPC H03M 13/09; H04L 1/0043; H03M 13/235; G06F 11/1004; H04L 1/0048

(57) ABSTRACT

A system for decoding storage data includes a memory that stores machine instructions and a processor coupled to the memory that executes the machine instructions to perform channel decoding based on a codeword to generate a data string. The processor further executes the machine instructions to perform source decoding based on the data string to generate a candidate symbol and identify one or more objects in a dictionary that have an initial symbol combination matching one or more symbols following an object separator based on the data string. The initial symbol combination terminates with the candidate symbol. The processor also executes the machine instructions to determine a joint probability based on a channel probability and a source probability that the candidate symbol is correct.

### TECHNICAL FIELD

The present disclosure relates generally to error detection and correction in communication systems and, more particularly, to error-correcting code memory.

### BACKGROUND

Error-detection and correction techniques are used to identify and rectify errors in computer communications data. Errors can sometimes be introduced into computer communications data, for example, by way of electromagnetic interference or background radiation incurred during transmissions through communications circuitry or storage in memory cells. Error-correcting code (ECC) introduces redundancy into communications data to permit detection of erroneous data and recovery of correct data.

Some error-correcting code techniques have been applied to computer storage data to reduce or eliminate data corruption. Typical encoding approaches have applied source coding techniques to convert each source symbol into a binary string and then channel coding techniques to add redundancy. Similarly, typical decoding approaches have applied channel decoding techniques to remove the added redundancy and then source decoding techniques to convert the binary strings into symbols.

For example, successive-cancellation (SC) decoding of polar codes has been applied, although the resulting error-rate performance demonstrated with finite-length codewords has not proven highly satisfactory. Successive-cancelation list (SCL) and cyclic redundancy check (CRC)-aided SCL decoding schemes have demonstrated relatively improved performance over SC decoding. Another approach has applied an iterative decoding method that alternates between low-density parity-check (LDPC) codes and dictionary information.

Nonetheless, ECC techniques providing relatively increased performance with practical codeword lengths and/or relatively decreased complexity would be desirable for use in memory or storage systems.

### SUMMARY

According to one embodiment of the present invention, a device for decoding storage data includes a memory that stores machine instructions and a processor coupled to the memory that executes the machine instructions to perform channel decoding based on a codeword to generate a data string. The processor further executes the machine instructions to perform source decoding based on the data string to generate a candidate symbol and identify one or more objects in a dictionary that have an initial symbol combination matching one or more symbols following an object separator based on the data siring. The initial symbol combination terminates with the candidate symbol. The processor also executes the machine instructions to determine a joint probability based on a channel probability and a source probability that the candidate symbol is correct.

According to another embodiment of the present invention, a computer-implemented method of decoding storage data includes performing channel decoding based on a codeword to generate a data string and performing source decoding based on the data string to generate a candidate symbol. The method further includes identifying one or more objects in a dictionary that have an initial symbol combination matching one or more symbols following an object separator based on the data string. The initial symbol combination terminates with the candidate symbol. The method also includes determining a first joint probability based on a channel probability and a source probability that the candidate symbol is correct.

According to yet another embodiment of the present invention, a computer program product for decoding storage data includes a non-transitory, computer-readable storage medium encoded with instructions adapted to be executed by a processor to implement performing channel decoding based on a codeword to generate a data string and performing source decoding based on the data string to generate a candidate symbol. The instructions are further adapted to implement identifying one or more objects in a dictionary that have an initial symbol combination matching one or more symbols following an object separator based on the data string. The initial symbol combination terminates with the candidate symbol. The instructions are also adapted to implement determining a first joint probability based on a channel probability and a source probability that the candidate symbol is correct.

The details of one or more embodiments of the invention are set forth in the accompanying drawings and the description below. Other features, objects, and advantages of the invention will be apparent from the description and drawings, and from the claims.

### DESCRIPTION OF THE DRAWINGS

FIG. 1 is a block diagram illustrating an exemplary joint source-channel decoder in accordance with an embodiment of the present invention.

FIG. 2 is a block diagram illustrating an exemplary joint source-channel coding storage system that can implement the joint source-channel decoder of FIG. 1.

FIG. 3 is a tree diagram illustrating a dictionary data structure that can be utilized by the joint source-channel decoder of FIG. 1.

FIG. 4 is tree diagram illustrating an updated dictionary data structure that can be utilized by the joint source-channel decoder of FIG. 1.

FIG. 5 is a flowchart representing an exemplary method of joint source-channel coding of storage data in accordance with an embodiment of the present invention.

FIG. 6 is a graph comparing block error rate and signal-to-noise ratio (SNR) in accordance with an embodiment of the present invention with some existing decoding procedures.

FIG. 7 Is a schematic view depicting an exemplary general computing system that can be employed in the joint source-channel decoder of FIG. 1 or in the joint source-channel coding storage system of FIG. 2.

### DETAILED DESCRIPTION

An embodiment of the present invention implements joint source-channel coding techniques that exploit structural correlations between source data and stored codewords. A dictionary contains information regarding objects related to the source data. A list decoding method jointly takes into account information regarding the read data distribution and the source data distribution to generate the retrieved data.

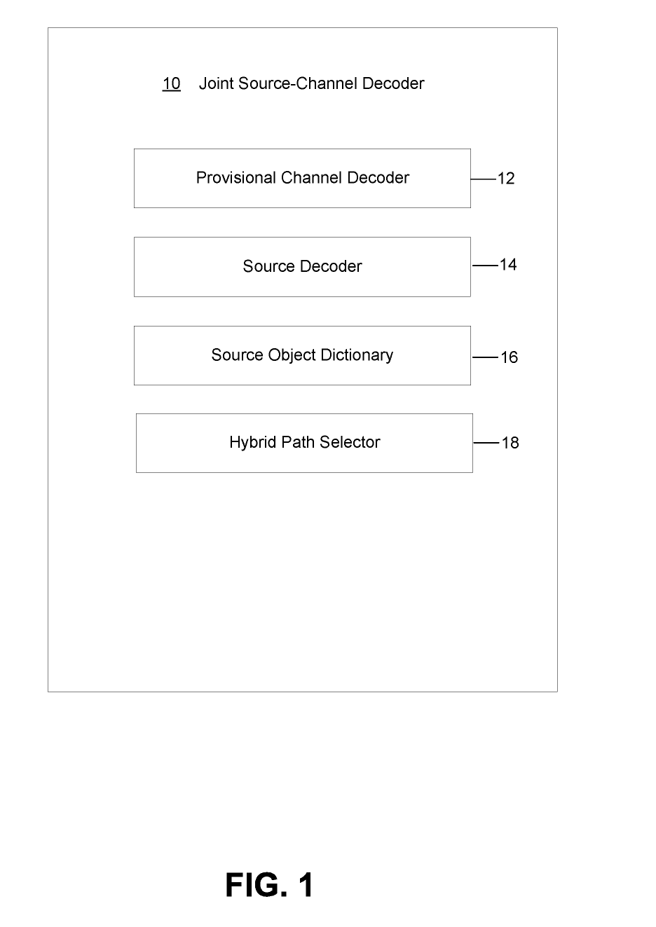

An embodiment of the present invention is shown in FIG. 1, which illustrates an exemplary joint source-channel decoder 10 that employs a joint source-channel decoding process in order to convert retrieved storage data into the original data symbols corresponding to stored source data. The joint source-channel decoder 10 includes a provisional channel decoder 12, a source decoder 14, source object dictionary 16 and a hybrid path selector 18.

The provisional channel decoder 12 receives a retrieved codeword from storage data and performs initial channel decoding to generate a provisional binary data string path, or multiple alternative paths, using any suitable channel decoding algorithm. The provisional channel decoder 12 removes channel coding redundancy from the retrieved storage data, while detecting and correcting errors in the retrieved storage data.

The source decoder 14 converts a segment of the provisional binary data string, or each of the alternative strings, into a candidate symbol corresponding to the stored source data type. For example, in an embodiment, the source data is English-language text, and the source decoder 14 converts a segment of the provisional binary data string into a next letter of a partial or whole word.

The source object dictionary 16 stores object-based information associated with the stored source data. For example, in an embodiment, the source data is English-language text, and the source object dictionary 16 stores a compendium of English-language words. In this example, the source symbol unit is a letter. The letters may be represented in any useful format, for example, in accordance with the seven-bit character codes established by the American Standard Code for Information Interchange (ASCII). In an embodiment, the source object dictionary 16 also stores the number of occurrences, or frequencies, with which stored words, as well as combinations of letters in partial words, appear in a corpus of documents related to the type of source data.

The hybrid path selector 18 receives the candidate symbol converted from the provisional binary data string and output from the source decoder 14 as feedback, along with source object information from the source object dictionary 16, and selects a limited number of the provisional binary data string paths to be retained based on estimated joint source-channel probabilities regarding each path based on the word frequency information received from the dictionary 16 and statistical channel input information.

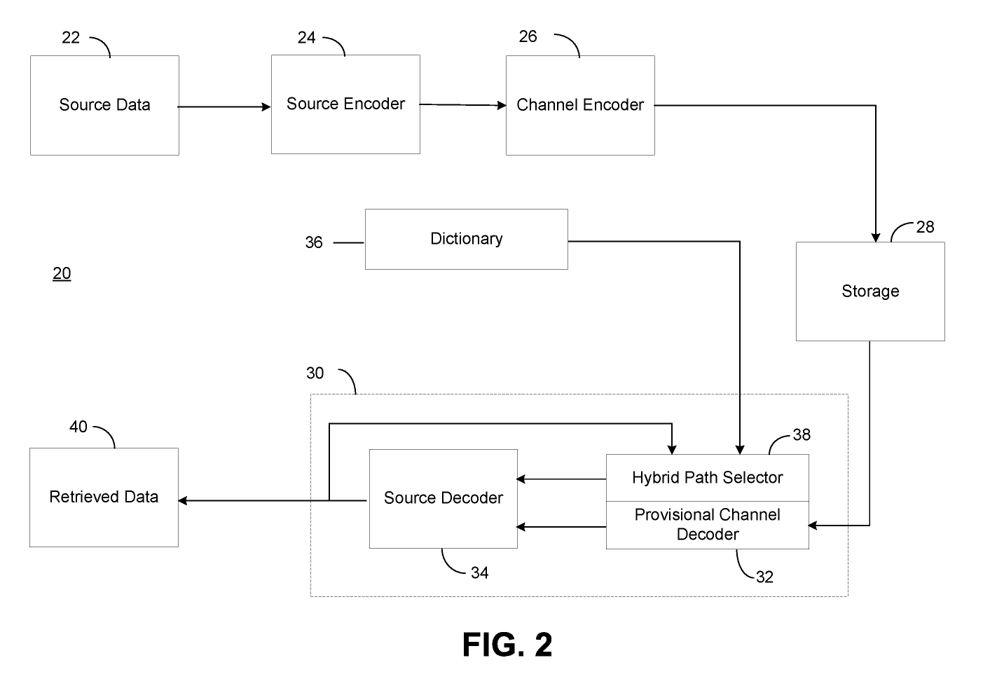

Another embodiment is shown in FIG. 2, which illustrates an exemplary joint source-channel coding storage system 20 that employs a joint source-channel coding process in order to efficiently transmit and store data while providing error detection and correction. The joint source-channel coding storage system 20 converts source data into redundant storage data, and converts retrieved storage data into source object symbols corresponding to the original source data. The joint source-channel coding storage system 20 can implement the joint source-channel decoder of FIG. 1.

The joint source-channel coding storage system 20 includes a source encoder 24, a channel encoder 26, a storage 28, and a joint, source-channel decoder 30. The source encoder 24 receives source data 22 (d) to be stored, including object-based data, for example, text, image, audio or video data, or any combination of these.

The source encoder 24 performs a source encoding procedure to convert symbols, such as individual letters, in the source data 22 into binary strings (U) that can be efficiently transmitted and stored. For example, in an embodiment, the source encoder 24 implements Huffman encoding. The associated Huffman tree may be based on empirical statistics extracted from the source data 22 or another corpus of related data, such as a larger corpus of general text sources, in the case that the source data 22 includes text data. The source encoder 24 also concatenates multiple binary strings corresponding to symbols to form a data string, for example, a block or frame, that corresponds to a sequence of source symbols.

The channel encoder 26 performs a channel, encoding procedure to convert the data string into a codeword (X) to be transmitted to and stored in the storage 28. For example, in an embodiment, the channel encoder 26 implements a polar code algorithm. The channel encoding procedure adds redundancy to the source data to allow for detection and correction of any errors in the subsequently retrieved data.

The joint source-channel decoder 30 converts retrieved storage data into objects, such as words. The joint source-channel decoder 30 includes a provisional channel decoder 32, a source decoder 34, a dictionary 36 and a hybrid path selector 38. The provisional channel decoder 32 receives a codeword retrieved from the storage 28 and-converts the retrieved codeword (Y), or a segment of the codeword, into a provisional data siring (Û), or multiple alternative provisional data strings. For example, in an embodiment, the provisional channel decoder 32 implements a successive-cancellation list (SCL) decoding technique for polar codes to determine alternative data strings that statistically most likely correctly represent the corresponding source data string at each SCL decoding stage.

As known in the art, successive-cancellation list decoding takes into account the channel input. The most probable retrieved data string paths, P(u₁^{N}|y₁^{N}), are selected at each decoding stage, for example, based on the assumption that the elements in the data string are independent and identically distributed (i.i.d.) according to the Bernoulli distribution with a probability of one-half (0.5). However, in object-based storage, the elements in the data string are correlated. Thus, prediction accuracy can be increased by taking into account information regarding the source, as well as the channel.

At each decoding stage, the source decoder 34 identifies a relevant segment of each of the alternative provisional data strings corresponding to symbols of the stored source data type and converts each segment into a provisional next symbol, or candidate symbol, corresponding to the stored source data type to generate a list of candidate symbol paths. For example, in an embodiment, the source data is English-language text, and the source decoder 34 converts a segment of each of the provisional data strings into a provisional next letter to generate a list of candidate letters.

The dictionary 36 stores object-based data associated with the stored source data or with the stored source data type. For example, in an embodiment, the source data is English-language text, and the dictionary 36 stores a compendium of English-language words including corresponding word frequencies. The dictionary 36 may be based on a corpus of documents. For example, in an-embodiment, the dictionary 36 includes words and the corresponding frequencies of those words occurring in a ten million-word excerpt from an encyclopedia.

At each decoding stage, the hybrid path selector 38 receives the candidate symbols as feedback from the output of the source decoder 34, and queries the dictionary 36 to verify whether or not each of the candidate symbols, when combined with predecessor symbols, corresponds to an initial symbol combination in an object found in the dictionary 36. Symbol combinations that do not correspond to the initial symbols of any object contained in the dictionary 36 are rejected.

The hybrid path selector 38 computes estimated joint source-channel probabilities for each of the alternative data string paths. Since the binary strings corresponding to symbols in each of the alternative data strings are correlated based on the underlying source objects, the probability associated with each alternative data string path given the retrieved codeword can be represented as follows:

P(u₁ⁱ|y₁^{N})∝P(y₁^{N}|u₁ⁱ)P(d₁^{j})

since:

$$\frac{P ( {u}_{1}^{i} , {y}_{1}^{N} )}{P ( {y}_{1}^{N} )} ∝ P ( {y}_{1}^{N} \vert {u}_{1}^{i} ) P ( {u}_{1}^{i} ) .$$

Thus, the joint source-channel probability, or joint probability, includes a channel probability component, P(y₁^{N}|u₁ⁱ), based on statistical channel information, and a source probability component, P(d₁^{j}), based on source information. The joint source-channel probability reflects the likelihood that a candidate symbol is correct, that is, the likelihood that the candidate symbol matches a corresponding source symbol in the source data. It should be noted that this joint probability computation assumes that individual objects, such as words in text, are independent such that the following equation holds true:

P(d₁^{j})=π^{j}ₖ₌₁P(dₖ)

Nevertheless, in some embodiments, this assumption may not be strictly true. For example, in the case of natural language text grammar provides additional correlation between words. As a result, in some embodiments, the joint source-channel probability computation may be further refined to reflect additional correlation that may exist among objects in the source data.

The hybrid path selector 38 determines a list including a limited number, L₂, of alternative data string paths that have the highest probabilities of correctly representing the corresponding source symbol or symbols. Thus, at each decoding stage, up to L₂ decoding paths are concurrently considered. For example, in an embodiment, a trimming or pruning procedure is used to remove candidate paths from a tree representing an object in the retrieved codeword, leaving only the L₂ most likely paths after each decoding stage. In an embodiment, the statistical determination of symbols and underlying binary data strings progresses on an object-by-object basis, for example, identifying individual objects between object separators, such as spaces or punctuation marks in text.

In an alternative embodiment, the hybrid path selector 38 performs an adaptive joint source-channel decoding procedure. For example, the hybrid path selector 38 begins by performing decoding implementing a relatively small list size, such as L₂=1. If the decoding procedure does not produce an acceptable result, the hybrid path selector 38 increases the list size, for example, by a factor of two, during each successive attempt until the decoding procedure is successful or until the list size reaches a predetermined maximum permitted size, Lₘₐₓ. If the decoding procedure does not succeed using the maximum list size, then a decoding error is declared and the procedure ends.

In practicality, the source object dictionary cannot contain all possible objects that may be encountered, such as misspelled words in text. Thus, in an embodiment, a dynamic dictionary is configured to automatically update the dictionary data structure with additional objects that are encountered in the source data but not included in the dictionary during the encoding process. The dynamic dictionary utilizes a tree structure to represent all words in the dictionary and store the number of occurrences of each corresponding combination of letters.

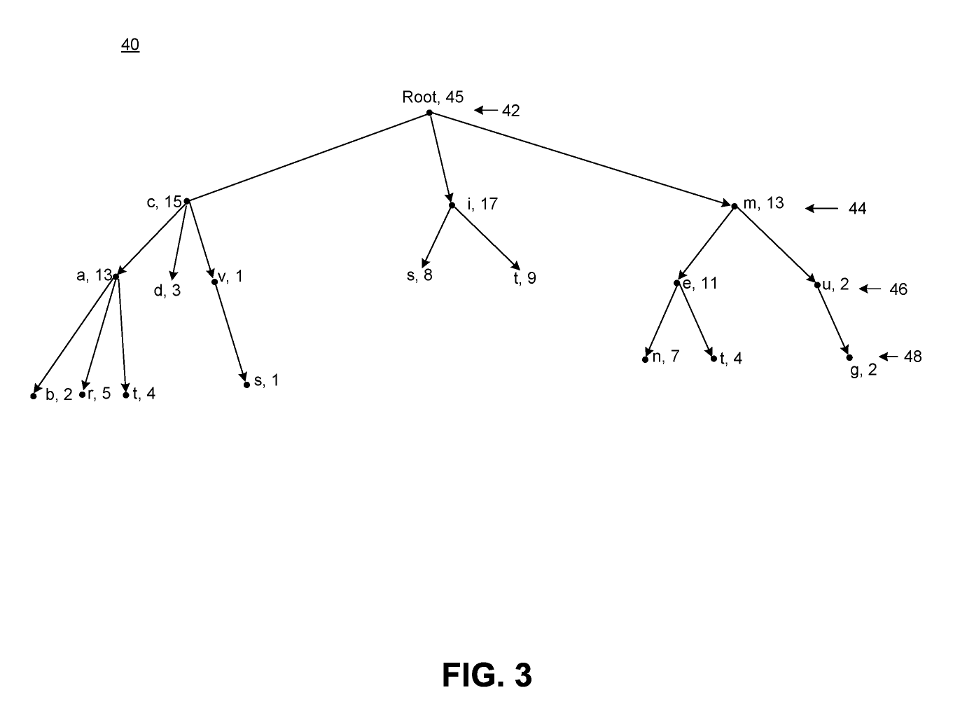

For example, referring to FIG. 3, an exemplary dictionary data structure 40 includes a tree structure that can be utilized by the joint source-channel decoder of FIG. 1, or by the joint source-channel coding storage system 20 of FIG. 2, to represent English-language text. The root node 42 points to first-letter nodes 44 representing the first letters at the beginning of all words in a corpus of documents. Each of the first-letter nodes 44 in turn points to second-letter nodes 46 representing all first and second letter combinations of words in the corpus. Similarly, each of the second-letter nodes 46 points to third-letter nodes 48 representing all first through third letter combinations of words in the corpus. Words of any length can be represented adding node levels to the dictionary data structure 40.

The root node 42 records the total number of words in the corpus. Each of the letter nodes 44, 46, 48 stores the represented letter and the marginal frequency of words in the corpus beginning with the corresponding combination of letters. Thus, the dictionary data structure 40 represents a source with the following words and corresponding number of occurrences, or frequency, of each word:

| Word | Count |
|---|---|
| cab | 2 |
| car | 5 |
| cat | 4 |
| cd | 3 |
| cvs | 1 |
| is | 8 |
| it | 9 |
| men | 7 |
| met | 4 |
| mug | 2 |

In some embodiments, the source object dictionary is statically configured previous to the encoding and decoding processes. However, if any additional objects are present in the source data, the static dictionary cannot recognize the new objects. Thus, in an alternative embodiment, a dynamic dictionary is configured to automatically update the dictionary data structure with additional objects encountered in the source data during encoding. For example, the source object dictionary 16 of FIG. 1 or the dictionary 36 of FIG. 2 can be implemented as a dynamic dictionary.

In an embodiment, the following procedure can be implemented to update the dynamic dictionary during the encoding process:

```
Input: string s[ ]
TreeNode* p = root;
for i = 1 to s.length( )
  if s[i] exists as the character of a child q of p
    p = q
  else
    create a TreeNode t and initiate the character as s[i],
      frequency as 1
    attach this TreeNode t as a child of p, then p = t
  end if
end for
```

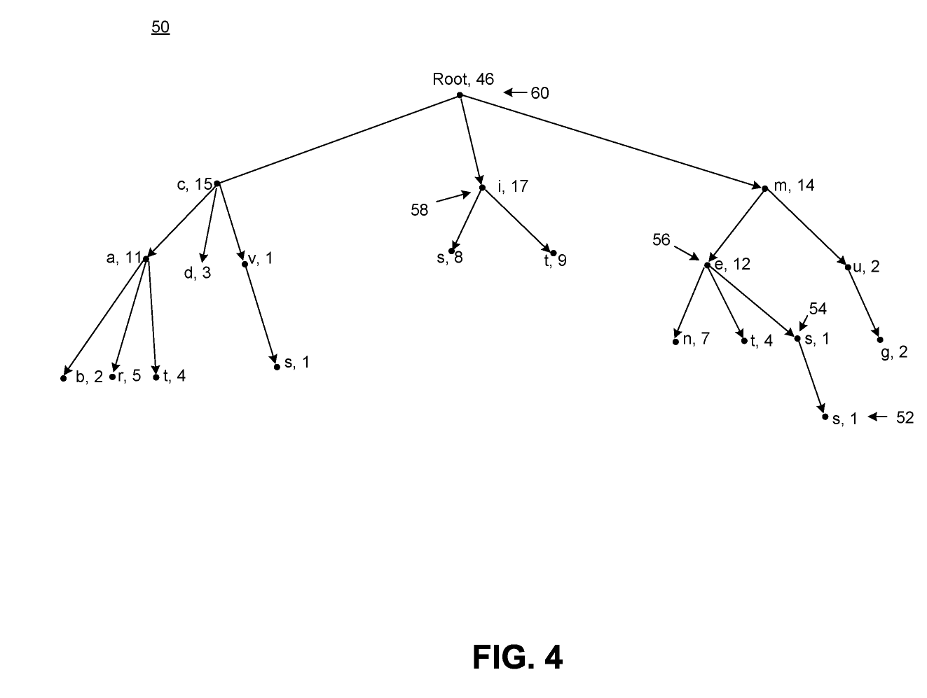

Referring to FIG. 4, an updated dictionary data structure 50 includes a tree structure adding the word “mess” to the dictionary data structure 40 of FIG. 3. The update adds the fourth-letter node 52 and increments the marginal frequencies stored at the corresponding third-letter node 54, second-letter node 56 and first-letter node 58. The update also increments the total word count stored at the mot node 60.

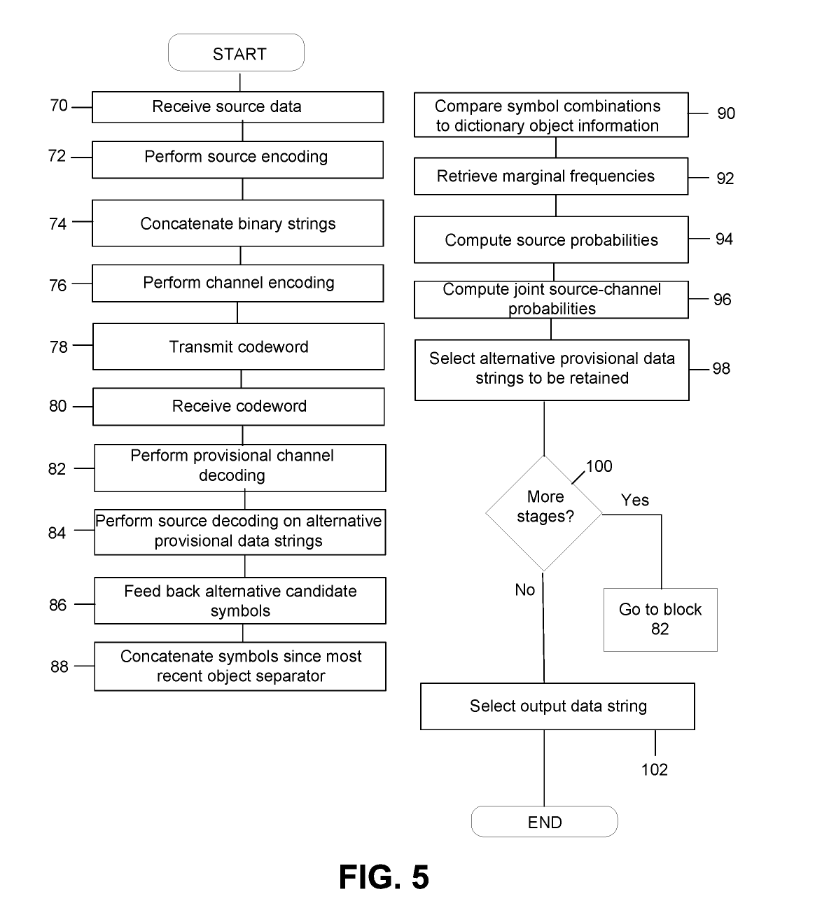

Referring now to FIG. 5, an exemplary process flow is illustrated that may be performed, for example, by the joint source-channel decoder 10 of FIG. 1, or by the joint source-channel coding storage system 20 of FIG. 2, to implement an embodiment of the method described in this disclosure for converting retrieved storage data into the original data symbols corresponding to stored source data. The process begins at block 70, where source data is received from an object-based source. For example, in an embodiment, text data from one or more electronic documents is received, including word objects, as described above.

In block 72, a source encoding procedure is performed on the source data symbols to generate binary strings. For example, in an embodiment, the source encoding procedure implements a Huffman code or other data compression algorithm, as described above. The binary strings representing individual symbols from the source data are concatenated to form a data string, in block 74.

In block 76, a channel encoding procedure is performed on the data string to generate a codeword. For example, in an embodiment, the channel encoding procedure implements a polar code or other data redundancy code algorithm, as described above. The codeword is transmitted through a communication channel, in block 78. For example, in an embodiment, the codeword is sent to a storage device, for example, a hard disk drive (HDD), a solid-state drive (SSD), or any other suitable data storage device.

In block 80, a retrieved codeword is received from the communication channel. For example, in an embodiment, the retrieved codeword is retrieved from the data storage device. At each decoding stage, a provisional channel decoding procedure is performed on the retrieved codeword to generate multiple alternative provisional data strings, in block 82.

For example, in an embodiment, a successive-cancellation list decoding algorithm for polar codes, or other data redundancy decoding algorithm, is implemented. Multiple alternative decoding paths, or provisional data strings, are concurrently considered at each decoding stage, as explained above. During each decoding stage the number of decoding paths initially is doubled before the tree structure is trimmed, or pruned, to discard all but a predetermined number of most probable paths. In various embodiments, the decoding stages may correspond to each successive bit of data in the retrieved codeword, a fixed number of data bits in the retrieved codeword, or any other suitable division of data in the retrieved codeword.

In block 84, a source decoding procedure is performed on the set of alternative provisional data strings to generate alternative candidate symbols. For example, in an embodiment, a Huffman decoding algorithm or other data compression algorithm is implemented to extract candidate symbols from the alternative provisional data strings, as described above. The candidate symbols are sent through a feedback loop, in block 86, for further validation regarding the channel decoding procedure.

In block 88, the alternative candidate symbols are concatenated with any previously decoded symbols following the most recent object separator encountered in the provisional data string. For example, in a text data string, the decoded letters following a space or punctuation are concatenated to form a partial or whole word.

The combinations of concatenated symbols, including the most recently decoded candidate symbol or symbols at the trailing end, in block 90, are compared to object information stored in a source object dictionary. The object information is reviewed to identify any objects in the dictionary with an initial symbol combination that matches the partial or whole object formed by the concatenated decoded symbols.

The marginal frequency, or number of occurrences, related to each symbol combination is retrieved from the dictionary, in block 92, as explained above. In block 94, source probabilities are computed for each of the alternative candidate symbols based on the marginal frequencies stored in the dictionary with respect to each combination of concatenated symbols, as explained above.

As an example, with reference to the dictionary data structure 50 of FIG. 4, if the candidate letters “n,” “t” and “s” are generated by the source decoding procedure in block 84, and these are concatenated with previously decoded letters “me” to form the partial or whole words “men,” “met” and “mes” in block 88, then the dictionary tree structure 50 may be traversed to determine corresponding marginal frequencies in block 90, and the following source probabilities may be computed in block 92, as follows:

$$P ( men ) = \frac{7}{45} = 0.1556$$

$$P ( met ) = \frac{4}{45} = 0.0889$$

$$P ( {mes}^{*} ) = \frac{1}{45} = 0.0222$$

In block 96, estimated joint source-channel probabilities are computed for each of the alternative provisional data string paths from block 82, as explained above. The joint source-channel probabilities combine the source probability regarding a particular source object or partial object with the channel probability regarding a particular retrieved data string, as explained above.

In block 98, the joint source-channel probabilities axe used to determine which of the alternative provisional data strings to retain at each stage of the joint source-channel decoding procedure. In an embodiment, a specified number of the alternative provisional data strings from block 82 having the highest joint source-channel probabilities are retained at each decoding stage. The additional alternative provisional data strings are trimmed or pruned from the data structure. In the case that no objects in the dictionary match the symbol combinations from block 88, then the corresponding source probability, and thus, the joint source-channel probability, equal zero and the corresponding candidate symbol or symbols from block 84, and any corresponding alternative data strings from block 82, are rejected.

In block 100, a determination is made regarding whether or not additional decoding stages are required to complete the decoding of the retrieved codeword from block 80. If so, then the process continues at block 82; otherwise, at the final decoding stage, a retrieved data string having the highest joint source-channel probability is selected from the list of alternative-data strings as output, in block 102.

The systems and methods described herein can offer advantages such as a joint source-channel coding scheme using polar codes having reduced complexity and improved performance. For example, embodiments do not require iterative decoding and can provide reduced block or frame error rates (FER) at relatively low signal-to-noise ratios (SNR) with respect to some existing methodologies. At relatively higher SNR, embodiments can provide substantial gain, demonstrating a similar waterfall slope with respect to some existing methodologies. Embodiments can tolerate higher raw bit error rates (BER) and thus extend the life of some types of storage media, such as solid-state devices (SSD) based on NAND flash technology.

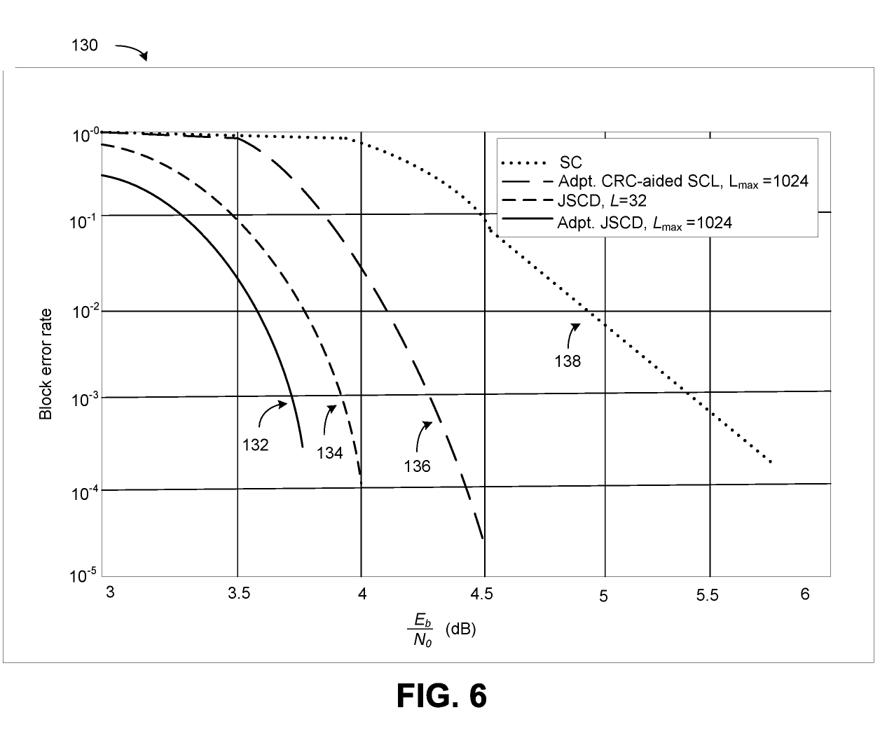

Referring to FIG. 6, a performance chart 130 plots block error rate against signal-to-noise ratio (energy per bit to noise power spectral density ratio, E_{b}/N₀) resulting from various decoding procedures performed with an English-language text sample. The adaptive joint source-channel (Lₘₐₓ=1024) decoding curve 132, performed in accordance with an embodiment of this disclosure, demonstrates a gain of more than 0.6 decibel with respect to some existing solutions. The joint source-channel (L=32) decoding curve 134, performed in accordance with an embodiment of this disclosure, also demonstrates significantly improved performance with respect to some existing solutions. For example, the performance chart illustrates the successive cancellation (SC) decoding curve 136 and the adaptive cyclic redundancy check (CRC)-aided SC list (SCL) (Lₘₐₓ=1024) decoding curve 138 showing results obtained in each case with the same English-language text sample.

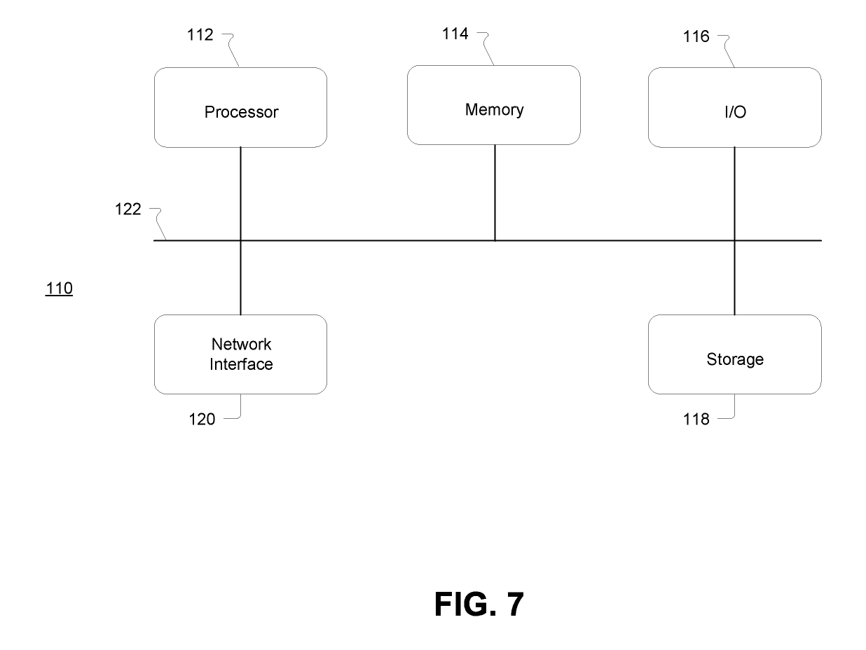

As illustrated in FIG. 7, an exemplary general computing device 110 that can be employed in the joint source-channel decoder 10 of FIG. 1, or the joint source-channel coding storage system 20 of FIG. 2, includes a processor 112, a memory 114, an input/output device (I/O) 116, a storage 118 and a network interface 120. The various components of the computing device 110 are coupled by a local data link 112, which in various embodiments incorporates, for example, an address bus, a data bus, a serial bus, a parallel bus, a storage bus, or any combination of these.

In some embodiments, the computing device 110 is coupled to a communication network by way of the network interface 120, which in various embodiments may incorporate, for example, any combination of devices, as well as any associated software or firmware, configured to couple processor-based systems, including moderns, access points, routers, network interface cards, LAN or WAN interfaces, wireless or optical interfaces and the like, along with any associated transmission protocols, as may be desired or required by the design.

The computing device 110 can be used, for example, to implement the functions of the components of the joint source-channel decoder 10 of FIG. 1 or the joint source-channel coding storage system 20 of FIG. 2. In various embodiments, the computing device 110 can include, for example, a server, a workstation, a mainframe computer, a controller (such as a memory or storage controller), a personal computer (PC), a desktop PC, a laptop PC, a tablet, a notebook, a personal digital assistant (PDA), a smartphone, a wearable device, or the like. Programming code, such as source code, object code or executable code, stored on a computer-readable medium, such as the storage 118 or a peripheral storage component coupled to the computing device 110, can be loaded into the memory 114 and executed by the processor 112 in order to perform the functions of the joint source-channel decoder 10.

Aspects of this disclosure are described herein with reference to flowchart illustrations or block diagrams, in which each block or any combination of blocks can be implemented by computer program instructions. The instructions may be provided to a processor of a general purpose computer, special purpose computer, or other programmable data processing apparatus to effectuate a machine or article of manufacture, and when executed by the processor the instructions create means for implementing the functions, acts or events specified in each block or combination of blocks in the diagrams.

In this regard, each block in the flowchart or block diagrams may correspond to a module, segment, or portion of code that includes one or more executable instructions for implementing the specified logical functions(s). It should also be noted that, in some alternative implementations, the functionality associated with any block may occur out of the order noted in the figures. For example, two blocks shown in succession may, in fact, be executed substantially concurrently, or blocks may sometimes be executed in reverse order.

A person of ordinary skill in the art will appreciate that aspects of this disclosure may be embodied as a device, system, method or computer program product. Accordingly, aspects of this disclosure, generally referred to herein as circuits, modules, components or systems, or the like, may be embodied in hardware, in software (including source code, object code, assembly code, machine code, micro-code, resident software, firmware, etc.), or in any combination of software and hardware, including computer program products embodied in a computer-readable medium having computer-readable program code embodied thereon.

It will be understood that various modifications may be made. For example, useful results still could be achieved if steps of the disclosed techniques were performed in a different order, and/or if components in the disclosed systems were combined in a different manner and/or replaced or supplemented by other components. Accordingly, other implementations are within the scope of the following claims.

What is claimed is:

1. A device for decoding storage data, comprising:
a memory that stores machine instructions; and
a processor coupled to the memory that executes the machine instructions to perform channel decoding based on a codeword to generate a data string, perform source decoding based on the data string to generate a candidate symbol, identify one or more objects in a dictionary that have an initial symbol combination matching one or more symbols following an object separator based on the data string, the initial symbol combination terminating with the candidate symbol, and determine a first joint probability based on a channel probability and a source probability that the candidate symbol is correct.

2. The device of claim 1, wherein the processor further executes the machine instructions to generate a plurality of alternative data strings based on the codeword, the plurality of alternative data strings including the data string, generate a plurality of alternative candidate symbols based oil the data string, the plurality of alternative candidate symbols including the candidate symbol, determine a plurality of joint probabilities that the plurality of alternative candidate data strings are correct, each of the plurality of joint probabilities corresponding to a respective alternative data string of the plurality of alternative data strings, the plurality of joint probabilities including the first joint probability, and select a predetermined number of the plurality of alternative candidate symbols based on the plurality of joint probabilities.

3. The device of claim 2, wherein the processor further executes the machine instructions to select an output data string from among the predetermined number of the plurality of alternative data strings based on the output data/string corresponding to the highest of the plurality of joint probabilities.

4. The device of claim 1, wherein the processor further executes the machine instructions to compute the source probability based on a frequency associated with the one or more objects in the dictionary.

5. The device of claim 4, wherein the frequency corresponds to the number of occurrences of the one or more objects in a corpus associated with a source associated with the codeword.

6. The device of claim 1, wherein the processor further executes the machine instructions to perform successive cancellation list decoding of a polar code and to perform decoding of a Huffman code.

7. The device of claim 1, wherein a source associated with the codeword comprises natural language text, the one or more objects including words and the one or more symbols including letters.

8. The device of claim 1, wherein the processor further executes the machine instructions to encode the codeword based on a source, encounter an additional object in the source that is not included in the dictionary during the encoding process, and add the additional object to the dictionary during the encoding process.

9. A method of decoding storage data, comprising:
performing channel decoding based on a codeword to generate a data string;
performing source decoding based on the data string to generate a candidate symbol;
identifying one or more objects in a dictionary that have an initial symbol combination matching one or more symbols following an object separator based on the data string, the initial symbol combination terminating with the candidate symbol; and
determining a first joint probability based on a channel probability and a source probability that the candidate symbol is correct.

10. The method of claim 9, further comprising:
generating a plurality of alternative data strings based on the codeword, the plurality of alternative data strings including the data string;
generating a plurality of alternative candidate symbols based on the data string, the plurality of alternative candidate symbols including the candidate symbol;
determining a plurality of joint probabilities that the plurality of alternative candidate data strings are correct, each of the plurality of joint probabilities corresponding to a respective alternative data string of the plurality of alternative data strings, the plurality of joint probabilities including the first joint probability; and
selecting a predetermined number of the plurality of alternative candidate symbols based on the plurality of joint probabilities.

11. The method of claim 10, further comprising selecting an output data string from among the predetermined number of the plurality of alternative data strings based on the output data string corresponding to the highest of the plurality of joint probabilities.

12. The method of claim 9, further comprising computing the source probability based on a frequency associated with the one or more objects in the dictionary.

13. The method of claim 12, wherein the frequency corresponds to the number of occurrences of the one or more objects in a corpus associated with a source associated with the codeword.

14. The method of claim 9, wherein performing channel decoding includes successive cancellation list decoding of a polar code, and performing source decoding includes decoding of a Huffman code.

15. The method of claim 9, wherein a source associated with the codeword comprises natural language text, the one or more objects including words and the one or more symbols including letters.

16. The method of claim 9, further comprising:
encoding the codeword based on a source;
encountering an additional object in the source that is not included in the dictionary during the encoding process; and
adding the additional object to the dictionary during the encoding process.

17. The method of claim 9, further comprising receiving the codeword from a storage device.

18. A computer program product for decoding storage data, comprising:
a non-transitory, computer-readable storage medium encoded with instructions adapted to be executed by a processor to implement;
performing channel decoding based on a codeword to generate a data string;
performing source decoding based on the data string to generate a candidate symbol;
identifying one or more objects in a dictionary that have an initial symbol combination matching one or more symbols following an object separator based on the data string, the initial symbol combination terminating with the candidate symbol; and
determining a first joint probability based on a channel probability and a source probability that the candidate symbol is correct.

19. The computer program product of claim 18, wherein the instructions are further adapted to implement:
generating a plurality of alternative data strings based on the codeword, the plurality of alternative data strings including the data string;
generating a plurality of alternative candidate symbols based on the data string, the plurality of alternative candidate symbols including the candidate symbol;
determining a plurality of joint probabilities that the plurality of alternative candidate data strings are correct, each of the plurality of joint probabilities corresponding to a respective alternative data string of the plurality of alternative data strings, the plurality of joint probabilities including the first joint probability; and
selecting a predetermined number of the plurality of alternative candidate symbols based on the plurality of joint probabilities.

20. The computer program product of claim 18, wherein performing channel decoding includes successive cancellation list decoding of a polar code, and performing source decoding includes decoding of a Huffman code.
